(19) United States
(12) Patent Application Publication
(10) Pub. No.: US 2024/0395678 A1
(43) Pub. Date: Nov. 28, 2024

(54) SEMICONDUCTOR DEVICE, METHOD OF MANUFACTURING SEMICONDUCTOR DEVICE, AND POWER CONVERSION DEVICE

(71) Applicant: Mitsubishi Electric Corporation, Tokyo (JP)

(72) Inventors: Yasunari HINO, Tokyo (JP); Kiyoshi ARAI, Tokyo (JP); Taketoshi SHIKANO, Tokyo (JP)

(73) Assignee: Mitsubishi Electric Corporation, Tokyo (JP)

(21) Appl. No.: 18/323,600

(22) Filed: May 25, 2023

(30) Foreign Application Priority Data
Jul. 20, 2022 (JP) 2022-115749

(51) Int. Cl. H01L 23/495; H01L 23/00; H01L 23/367; H01L 23/373; H02M 1/08

(52) U.S. Cl. CPC H01L 23/49568; H01L 23/367; H01L 23/3736; H01L 24/32; H01L 24/33; H01L 24/83; H02M 1/08; H01L 2224/32245; H01L 2224/33181; H01L 2224/83; H02M 7/53871

(57) ABSTRACT

A semiconductor device with improved reliability and a power conversion device including the semiconductor device are provided. A semiconductor device includes a semiconductor element, a first heat dissipation substrate, a second heat dissipation substrate, and a heat dissipation block. The semiconductor element has an electrode. The semiconductor element is mounted on the first heat dissipation substrate. The heat dissipation block is disposed to be opposed to the electrode. The second heat dissipation substrate is disposed on a side opposite to the electrode as viewed from the heat dissipation block. The bonding material covers a side surface of the heat dissipation block and is in contact with the electrode of the semiconductor element and the second heat dissipation substrate.

### BACKGROUND OF THE INVENTION

### Field of the Invention

The present disclosure relates to a semiconductor device, a method of manufacturing a semiconductor device, and a power conversion device.

### Description of the Background Art

With recent movement toward decarbonized society, semiconductor devices typified by power semiconductor devices are used not only in home appliance applications such as air conditioners but also in vehicle applications such as electric cars and hybrid cars, and railroad applications (see, for example, Japanese Patent Laying-Open No. 2013-239486 and Japanese Patent Laying-Open No. 2020-188163). In Japanese Patent Laying-Open No. 2013-239486, in order to ensure bonding strength, a terminal having a through hole and an electrode of a semiconductor element are bonded by a bonding material with a heat dissipation member interposed. In Japanese Patent Laying-Open No. 2020-188163, a conductor plate and a semiconductor element are bonded with a conductor spacer interposed, and the conductor plate is bonded to a part of conductor spacer by solder and electrically connected in a semiconductor device.

### SUMMARY OF THE INVENTION

However, since the semiconductor devices described above are applied to a wide variety of products, the frequency of use under a high load environment (for example, under a high temperature environment or under a vibrations environment) is increasing, and durability of semiconductor devices is desired. In this way, there is a demand for further improvement in reliability typified by durability for conventional semiconductor devices.

The present disclosure is made to solve the problem as described above, and an object of the present disclosure is to provide a semiconductor device with improved reliability, and a power conversion device including the semiconductor device.

A semiconductor device according to the present disclosure includes a semiconductor element, a first heat dissipation substrate, a second heat dissipation substrate, and a heat dissipation block. The semiconductor element has an electrode. The semiconductor element is mounted on the first heat dissipation substrate. The heat dissipation block is disposed to be opposed to the electrode. The second heat dissipation substrate is disposed on a side opposite to the electrode as viewed from the heat dissipation block. A bonding material covers a side surface of the heat dissipation block and is in contact with the electrode of the semiconductor element and the second heat dissipation substrate.

A power conversion device according to the present disclosure includes a main conversion circuit, a drive circuit, and a control circuit. The main conversion circuit has the semiconductor device described above. The main conversion circuit converts input power and outputs the converted power. The drive circuit outputs a drive signal for driving the semiconductor device to the semiconductor device. The control circuit outputs a control signal for controlling the drive circuit to the drive circuit.

A method of manufacturing a semiconductor device according to the present disclosure includes the steps of preparing, mounting a semiconductor element, bonding the semiconductor element, mounting a second heat dissipation substrate, and bonding the second heat dissipation substrate. In the step of preparing, a first heat dissipation substrate and a semiconductor element having an electrode are prepared. In the step of mounting a semiconductor element, the semiconductor element is mounted on the first heat dissipation substrate with a first bonding material interposed. In the step of bonding the semiconductor element, the first bonding material is heated to bond the semiconductor element to the first heat dissipation substrate with the first bonding material interposed. In the step of mounting a second heat dissipation substrate, a heat dissipation block is mounted on the electrode of the semiconductor element with a second bonding material interposed, and a second heat dissipation substrate is further mounted on the heat dissipation block with a third bonding material interposed. In the step of bonding the second heat dissipation substrate, the second bonding material and the third bonding material are heated to allow the second bonding material and the third bonding material to cover the side surface of the heat dissipation block and to bond the electrode of the semiconductor element and the second heat dissipation substrate.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first embodiment.

FIG. 2 is a partially-enlarged cross-sectional view of region II in FIG. 1.

FIG. 3 is a partially-enlarged cross-sectional view showing a modification of the semiconductor device according to the first embodiment.

FIG. 4 is a partially-enlarged cross-sectional view showing a modification of the semiconductor device according to the first embodiment.

FIG. 5 is a flowchart of a method of manufacturing a semiconductor device according to the first embodiment.

FIG. 6 is a partially-enlarged cross-sectional view before melting of a bonding material in a modification of the method of manufacturing a semiconductor device according to the first embodiment.

FIG. 7 is a partially-enlarged cross-sectional view after melting of the bonding material in a modification of the method of manufacturing a semiconductor device according to the first embodiment.

FIG. 8 is a cross-sectional view of a semiconductor device according to a second embodiment.

FIG. 9 is a cross-sectional view showing a modification of the semiconductor device according to the second embodiment.

FIG. 10 is a partially-enlarged cross-sectional view of a semiconductor device according to a third embodiment before melting of the bonding material.

FIG. 11 is a partially-enlarged cross-sectional view of a semiconductor device according to the third embodiment after melting of the bonding material.

FIG. 12 is a partially-enlarged cross-sectional view showing a modification of the semiconductor device according to the third embodiment.

FIG. 13 is a partially-enlarged cross-sectional view of a semiconductor device according to a fourth embodiment.

FIG. 14 is a partially-enlarged cross-sectional view showing a modification of the semiconductor device according to the fourth embodiment.

FIG. 15 is a partially-enlarged cross-sectional view of a semiconductor device according to a fifth embodiment.

FIG. 16 is a partially-enlarged cross-sectional view showing a modification of the semiconductor device according to the fifth embodiment.

FIG. 17 is a partially-enlarged cross-sectional view showing a modification of the semiconductor device according to the fifth embodiment.

FIG. 18 is a partially-enlarged cross-sectional view showing a modification of the semiconductor device according to the fifth embodiment.

FIG. 19 is a block diagram showing a configuration of a power conversion system in which a power conversion device is applied according to a sixth embodiment.

### DESCRIPTION OF THE PREFERRED EMBODIMENTS

Embodiments of the present disclosure will be described below. In the following drawings, the same or corresponding parts are denoted by the same reference numerals unless otherwise specified, and a description thereof is not repeated.

### First Embodiment

### <Configuration of Semiconductor Device>

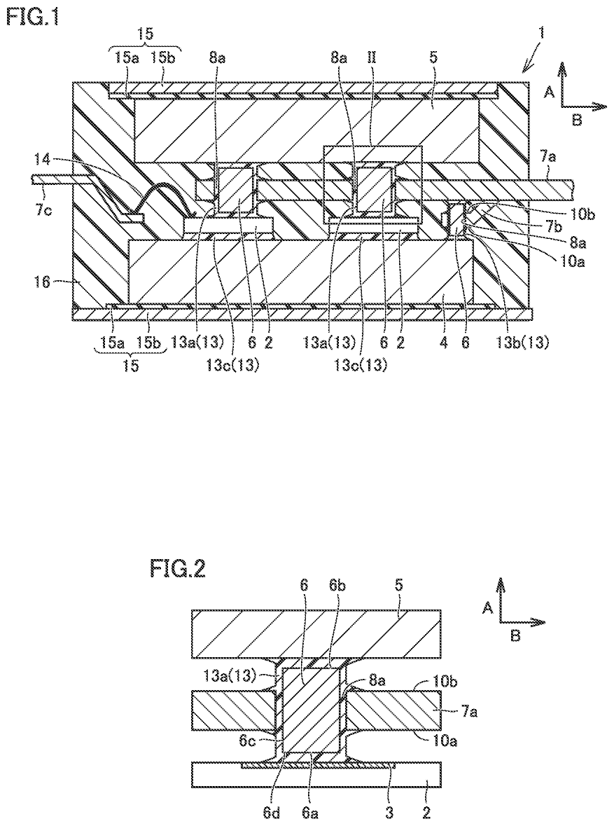

FIG. 1 is a cross-sectional view of a semiconductor device 1 according to a first embodiment. FIG. 2 is a partially-enlarged cross-sectional view of semiconductor device 1 in region II in FIG. 1.

Semiconductor device 1 shown in FIG. 1 and FIG. 2 is, for example, a power semiconductor device and mainly includes a semiconductor element 2, a first heat dissipation substrate 4, a second heat dissipation substrate 5, a heat dissipation block 6, a terminal 7a, a terminal 7b, a terminal 7c, a metal wire interconnection 14, an insulating heat dissipation sheet 15, and a sealing resin 16. As shown in FIG. 2, semiconductor element 2 has an electrode 3. As shown in FIG. 1, semiconductor element 2 is mounted on a surface (upper surface) of first heat dissipation substrate 4 with a joint section 13c interposed. Semiconductor element 2 has electrode 3 on a surface (upper surface) opposite to a surface (bottom surface) opposed to first heat dissipation substrate 4. Second heat dissipation substrate 5 is disposed on a side opposite to first heat dissipation substrate 4 as viewed from semiconductor element 2.

Second heat dissipation substrate 5 is connected to electrode 3 of semiconductor element 2 through joint section 13a formed of a bonding material 13. Terminal 7a and terminal 7b each have a first through hole 8a. Terminal 7a is disposed between electrode 3 of semiconductor element 2 and second heat dissipation substrate 5. Heat dissipation block 6 is disposed in the inside of first through hole 8a of terminal 7a.

Electrode 3 of semiconductor element 2 and second heat dissipation substrate 5 are connected to terminal 7a by joint section 13a. Joint section 13a fills the inside of first through hole 8a of terminal 7a so as to cover the outer periphery of heat dissipation block 6. That is, electrode 3 of semiconductor element 2 and second heat dissipation substrate 5 are connected to a region having first through hole 8a of terminal 7a by joint section 13a.

First heat dissipation substrate 4 is connected to terminal 7b by a joint section 13b formed of bonding material 13. Heat dissipation block 6 is disposed in the inside of first through hole 8a of terminal 7b. Joint section 13b fills the inside of first through hole 8a of terminal 7b so as to cover the outer periphery of heat dissipation block 6. First heat dissipation substrate 4 is connected to a region having first through hole 8a of terminal 7b by joint section 13b. Terminal 7c is connected, for example, to electrode 3 that is the control electrode of semiconductor element 2 through metal wire interconnection 14. First heat dissipation substrate 4 and second heat dissipation substrate 5 are connected to insulating heat dissipation sheets 15 at their respective surfaces (bottom surface or outer peripheral surface) opposite to the surfaces facing each other.

As shown in FIG. 1, two semiconductor elements 2 are mounted on the surface of first heat dissipation substrate 4. Two semiconductor elements 2 each include electrode 3 (see FIG. 2). Electrodes 3 of two semiconductor elements 2 are each connected to second heat dissipation substrate 5 and terminal 7a by joint section 13a. In other words, terminal 7a has first through hole 8a in a region located above semiconductor element 2. In semiconductor device 1 shown in FIG. 1, terminal 7a has two first through holes 8a. Terminal 7a extends from above two semiconductor elements 2 to the outside of sealing resin 16. Terminal 7b is connected to an outer periphery of the upper surface of first heat dissipation substrate 4 by joint section 13b. In a cross section shown in FIG. 1, terminal 7c extends along a direction in which terminal 7a extends.

Semiconductor element 2, first heat dissipation substrate 4, second heat dissipation substrate 5, a part of terminal 7a, a part of terminal 7b, and a part of terminal 7c are covered with sealing resin 16. A part of each of terminal 7a, terminal 7b, and terminal 7c extends from the surface of sealing resin 16 to the outside so as to connect to an external device outside of sealing resin 16. Terminal 7a, terminal 7b, and terminal 7c may be bent, for example, by forming at a portion extending to the outside of sealing resin 16. The above portions of terminal 7a, terminal 7b, and terminal 7c are connected to conductors (not shown) such as interconnections or terminals for electrically connected to a circuit board or another semiconductor device. The conductor and the above portion may be connected by any method and, for example, a fixing member such as screw may be used to fix the conductor and the above portion.

As shown in FIG. 1, the circuit configuration of semiconductor device 1 is a 2in1 type in which two semiconductor elements 2 are mounted in one module. The circuit configuration of semiconductor device 1 indicates, for example, an upper arm or a lower arm in an inverter circuit. The circuit configuration of semiconductor device 1 is not necessarily a 2in1 type. For example, a 1in1 type or a 6in1 type may be employed as the circuit configuration.

Semiconductor element 2 is power semiconductor element 2 for controlling power. The number of semiconductor elements 2 mounted on semiconductor device 1 is at least one or more. A plurality of semiconductor elements 2 may be mounted according to the specifications of semiconductor device 1. Semiconductor element 2 may be formed, for example, using a material such as silicon carbide (SiC), gallium nitride (GaN), gallium oxide (Ga₂O₃), or diamond. A wide-bandgap semiconductor material with a wider bandgap compared with such silicon can be used as a base material of semiconductor element 2. When a wide-bandgap semiconductor material is used as a base material, semiconductor device 1 with high efficiency and compatible with high temperatures can be obtained. In particular, when bonding material 13 forming joint section 13a is a sintered material made of silver (Ag) or the like, heat resistance of joint section 13a is improved. In this case, power semiconductor element 2 of silicon carbide operable at high temperatures can be used suitably. As a result, semiconductor device 1 operable at higher temperatures than a semiconductor element made of silicon as a base material can be implemented.

Semiconductor element 2 may be of any kind. For example, an insulated gate bipolar transistor (IGBT), a metal oxide semiconductor field effect transistor (MOSFET), or a Schottky barrier diode can be used. For example, semiconductor element 2 may be a reverse conducting IGBT (RC-IGBT) having an IGBT and a freewheeling diode integrated on one semiconductor chip. The length of one side of semiconductor element 2 is, for example, 1.5 mm or more and 15 mm or less.

As shown in FIG. 1, first heat dissipation substrate 4 and second heat dissipation substrate 5 are connected to insulating heat dissipation sheets 15 at their respective surfaces (bottom surface or outer peripheral surface) opposite to the surfaces facing each other. The material forming each of first heat dissipation substrate 4, second heat dissipation substrate 5, and heat dissipation block 6 may be any material that has high thermal conductivity. For example, first heat dissipation substrate 4, second heat dissipation substrate 5, and heat dissipation block 6 may be formed of a metal material such as copper (Cu), aluminum (Al), or copper-molybdenum (CuMo) alloy.

Alternatively, first heat dissipation substrate 4, second heat dissipation substrate 5, and heat dissipation block 6 may be formed of a composite material such as silicon carbide-aluminum composite material (AlSiC) or silicon carbide-magnesium composite material (MgSiC).

Insulating heat dissipation sheets 15 each include an insulating layer 15a and a metal layer 15b. Insulating layers 15a are connected to the bottom surfaces of first heat dissipation substrate 4 and second heat dissipation substrate 5 (the respective surfaces opposite to the surfaces facing each other of first heat dissipation substrate 4 and second heat dissipation substrate 5). Metal layers 15b are connected to the surfaces opposite to the surfaces connected to first heat dissipation substrate 4 and second heat dissipation substrate 5 in insulating layers 15a. Insulating heat dissipation sheet 15 has a laminated structure (two-layer structure) in which insulating layer 15a and metal layer 15b are laminated. In metal layer 15b, the surface opposite to the surface connected to insulating layer 15a is exposed from sealing resin 16. Insulating heat dissipation sheet 15 may not necessarily have a two-layer structure. In other words, insulating heat dissipation sheet 15 may include insulating layer 15a and a plurality of other metal layers 15b. For example, two or more metal layers 15b are laminated in insulating heat dissipation sheet 15.

The thermal conductivity of insulating heat dissipation sheet 15 is, for example, 2 W/(m·K) or more and 18 W/(m·K) or less. The thickness of insulating heat dissipation sheet 15 is, for example, 0.1 mm or more and 0.2 mm or less. Insulating layer 15a may be formed of, for example, a resin containing filler. For example, filler containing alumina (Al₂O₃), aluminum nitride (AlN), silicon nitride (Si₃N₄), silicon dioxide (SiO₂), or boron nitride (BN) can be used as the filler. A resin filled with the filler as described above can be used as the material of insulating layer 15a. For example, epoxy resin can be used as the resin. The material forming metal layer 15b includes a metal with high thermal conductivity. For example, copper (Cu) or aluminum (Al) can be used as the metal.

As shown in FIG. 1 and FIG. 2, terminal 7a has first through hole 8a. First through hole 8a is filled with bonding material 13, and joint section 13a is formed such that terminal 7a is connected to electrode 3 of semiconductor element 2 and second heat dissipation substrate 5. Terminal 7a has a first terminal main surface 10a opposed to electrode 3 of semiconductor element 2 and a second terminal main surface 10b opposite to first terminal main surface 10a. Joint section 13a is formed such that the interface between joint section 13a and terminal 7a extends not only on the side surface inside of first through hole 8a but also on first terminal main surface 10a and second terminal main surface 10b of terminal 7a. Joint section 13b is formed in the same manner as terminal 7a such that terminal 7b is connected to first heat dissipation substrate 4. Joint section 13b is formed such that the interface between joint section 13b and terminal 7b extends not only on the side surface inside of first through hole 8a but also on first terminal main surface 10a and second terminal main surface 10b of terminal 7b. First through hole 8a is formed by a chemical process such as etching or a physical process such as machining.

The material forming terminal 7a, terminal 7b, and terminal 7c is, for example, copper (Cu). The material forming terminal 7a, terminal 7b, and terminal 7c is any material that has electrical conductivity as well as heat dissipation properties. For example, the material forming terminal 7a, terminal 7b, and terminal 7c may be an alloy containing copper (Cu) or aluminum (Al), or a composite material in which these metals are laminated.

The thickness of terminal 7a, terminal 7b, and terminal 7c is, for example, 0.3 mm or more and 1.2 mm or less. Terminal 7a, terminal 7b, and terminal 7c constitute an integrated lead frame until tie bar cut or lead cut is performed in a manufacturing process described later. The respective thicknesses of terminal 7a, terminal 7b, and terminal 7c in an A direction shown in FIG. 1 and the respective widths of terminal 7a, terminal 7b, and terminal 7c in a direction vertical to the drawing sheet of FIG. 1 may be changed as appropriate in accordance with the capacity of current flowing through terminal 7a, terminal 7b, and terminal 7c. For example, the capacity of current flowing through metal wire interconnection 14 connected to electrode 3 that is the control electrode of semiconductor element 2 is relatively smaller than the capacity of current flowing through terminal 7a and terminal 7b. The thickness and width of terminal 7c therefore may be smaller than those of terminal 7a and terminal 7b. As a result, semiconductor device 1 can be reduced in size. In recent years, the capacity of current requested for semiconductor device 1 tends to be increased. For example, the rating current of semiconductor device 1 sometimes exceeds 1000 A. In such a case, the thickness of terminal 7a and terminal 7b may exceed 1.2 mm described above.

The metal forming metal wire interconnection 14 is, for example, a metal containing any one selected from the group consisting of aluminum (Al), copper (Cu), silver (Ag), and gold (Au). Metal wire interconnection 14 may be a metal of an alloy selected from the above group. Metal wire interconnection 14 is bonded to terminal 7c and electrode 3 that is the control electrode of semiconductor element 2 by pressurization and ultrasonic vibrations. Metal wire interconnection 14 is an interconnection allowing current to flow for controlling semiconductor element 2. Thus, the capacity of current required for metal wire interconnection 14 is relatively small. Accordingly, the joint area between metal wire interconnection 14, and electrode 3 that is the control electrode of semiconductor element 2 and terminal 7c can be reduced. Thus, the diameter of metal wire interconnection 14 is, for example, 0.02 mm or more and 0.2 mm or less.

The material serving as a main component of sealing resin 16 is, for example, a thermosetting resin. For example, epoxy resin can be used as the thermosetting resin. The above material forming sealing resin 16 may be a resin having thermosetting properties as well as elasticity, adhesion, heat resistance, and insulation properties in accordance with the outer size and internal structure of semiconductor device 1. For example, in addition to epoxy resin, silicone resin, phenolic resin, polyimide resin or the like may be used as the material. Sealing resin 16 may contain dispersed fine particles or filler in order to ensure the strength and thermal conductivity as semiconductor device 1. The material of fine particles and filler may be, for example, an inorganic ceramic material. The inorganic ceramic material is, for example, alumina (Al₂O₃), aluminum nitride (AlN), silicon nitride (Si₃N₄), silicon dioxide (SiO₂), boron nitride (BN), diamond, silicon carbide (SiC), or boron trioxide (B₂O₃). Sealing resin 16 can contain fine particles or filler to improve heat dissipation from heating semiconductor element 2 to the outside of semiconductor device 1.

Here, as shown in FIG. 1 and FIG. 2, semiconductor device 1 according to the present first embodiment is characterized in that electrode 3 of semiconductor element 2, terminal 7a, and second heat dissipation substrate 5 are each bonded around heat dissipation block 6 by bonding material 13. Specifically, as shown in FIG. 2, the outer periphery of heat dissipation block 6 includes a first heat dissipation block main surface 6a facing electrode 3 of semiconductor element 2, a second heat dissipation block main surface 6b opposite to first heat dissipation block main surface 6a, and a heat dissipation block side surface 6c that is a side surface connecting first heat dissipation block main surface 6a to second heat dissipation block main surface 6b. Joint section 13a that bonds each of electrode 3 of semiconductor element 2, terminal 7a, and second heat dissipation substrate 5 is formed such that bonding material 13 covers the outer periphery of heat dissipation block 6. In this way, the provision of such joint section 13a that covers the outer periphery of heat dissipation block 6 can improve the durability of joint section 13a. For example, in the absence of heat dissipation block 6, if cracking due to stress or distortion occurs in joint section 13a during operation of the power semiconductor device, disconnection is likely to occur during operation of the power semiconductor device, because joint section 13a is brittle and cracking spreads fast. On the other hand, when heat dissipation block 6 is provided in the inside of joint section 13a, the possibility of disconnection during operation of semiconductor device 1 is significantly reduced, because even if cracking occurs in joint section 13a, heat dissipation block 6 with a strength higher than joint section 13a prevents spread of the cracking in joint section 13a. Further, since bonding material 13 bonds heat dissipation block 6 so as to cover the entire outer periphery, rather than only a part of the outer periphery, the strength of joint section 13a is improved by the additional amount of bonding material 13. As a result, semiconductor device 1 in which high reliability is ensured can be obtained.

When a part of the outer periphery of heat dissipation block 6 is in contact with electrode 3 of semiconductor element 2, the side surface of first through hole 8a, or second heat dissipation substrate 5, the other part may be covered with bonding material 13. For example, in a modification of a method of manufacturing semiconductor device 1 described later, in which heat dissipation block 6 is mounted on electrode 3 without bonding material 13 interposed, and bonding material 13 disposed on heat dissipation block 6 is heated, as shown in FIG. 7, first heat dissipation block main surface 6a is directly connected to electrode 3, and joint section 13a is formed such that second heat dissipation block main surface 6b and heat dissipation block side surface 6c are covered with bonding material 13. Further, as shown in FIG. 12, joint section 13a may be formed such that first heat dissipation block main surface 6a is directly connected to electrode 3 of semiconductor element 2, a part of heat dissipation block side surface 6c is directly connected to the side surface of first through hole 8a of terminal 7a, and a portion of heat dissipation block side surface 6c that is not directly connected to the side surface of first through hole 8a and second heat dissipation block main surface 6b are covered with bonding material 13. Further, second heat dissipation substrate 5 may be in direct contact with second heat dissipation block main surface 6b. In other words, only electrode 3 of semiconductor element 2, second heat dissipation substrate 5, terminal 7a, and bonding material 13 can be directly connected to the outer periphery of heat dissipation block 6.

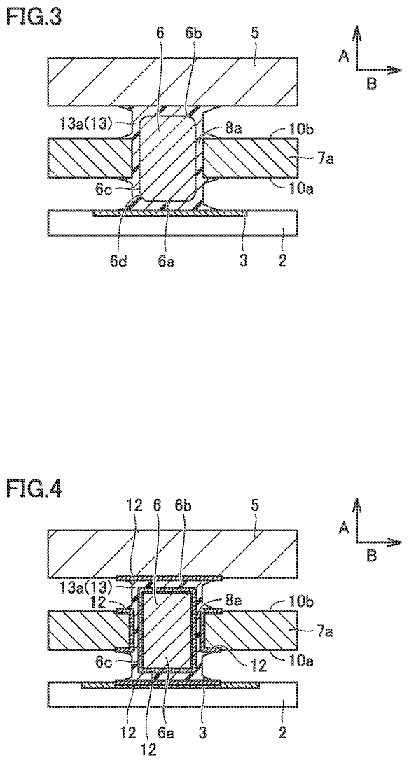

As shown in FIG. 3, a corner 6d of heat dissipation block 6 may have a rounded or chamfered shape. During operation of the power semiconductor device, high stress and distortion occur at joint section 13a near corner 6d of heat dissipation block 6 and therefore cracking is likely to occur. Thus, corner 6d of heat dissipation block 6 is rounded or chamfered so that stress and distortion in corner 6d is reduced, and as a result, cracking in joint section 13a can be suppressed.

The material of bonding material 13 used in the above semiconductor device 1 is, for example, any one selected from the group consisting of solder, sintered material, and adhesive. In a case where solder that is a conductive metal containing tin (Sn) is used as bonding material 13, it is preferable that when solder serving as bonding material 13 is melted, the solder wets well not only the side surface of first through hole 8a but also a region adjacent to first through hole 8a at first terminal main surface 10a and second terminal main surface 10b of terminal 7. In this case, the joint area at the interface between bonding material 13 and terminal 7 can be increased, so that the bonding strength at the interface can be ensured. For example, as shown in FIG. 2, joint section 13a that bonds terminal 7a and semiconductor element 2 can be shaped like a rivet. In this case, the interface between joint section 13a and terminal 7a is formed to extend not only on the side surface of first through hole 8a but also on first terminal main surface 10a and second terminal main surface 10b of terminal 7a. In other words, in first terminal main surface 10a and second terminal main surface 10b of terminal 7a, a portion adjacent to first through hole 8a is covered with a part of joint section 13a. The surface of a portion of joint section 13a that extends on first terminal main surface 10a or second terminal main surface 10b of terminal 7a is formed in a curved surface. The curved surface may be, for example, a curved surface recessed toward heat dissipation block 6.

Semiconductor element 2 generates heat during operation of semiconductor device 1. Thus, a sintered material containing fine particles of metal including silver (Ag) or copper (Cu) high in heat dissipation may be used as joint section 13a that is bonding material 13. In a case where joint section 13a is a sintered material, a solvent contained in the sintered material is volatilized well in a process of heating the sintered material serving as joint section 13a disposed in the inside of first through hole 8a, because first through hole 8a provided in terminal 7 is open at second terminal main surface 10b that is the upper surface. Thus, the solvent can be reliably removed from the sintered material serving as joint section 13a. Such an effect can be achieved similarly in joint section 13b disposed in first through hole 8a of terminal 7b.

Examples of the solvent include an organic coating provided on surfaces of metal fine particles so that metal fine particles do not aggregate, and a solvent mixed with metal fine particles for making the sintered material into paste.

Here, if a large amount of solvent is left in joint section 13a after the process of heating the sintered material serving as joint section 13a, voids attributable to the solvent are produced in joint section 13a. As a result, the inside of first through hole 8a is not filled with bonding material 13, and the strength of joint section 13a and joint section 13b becomes insufficient. Further, if large voids are formed in joint section 13a and joint section 13b, the reliability, lifetime, and thermal conductivity of joint section 13a and joint section 13b are deteriorated. On the other hand, in semiconductor device 1 according to the present embodiment, when a sintered material is used as bonding material 13, the solvent in the sintered material can be removed well from joint section 13a and joint section 13b in the heating process, because first through hole 8a penetrates terminal 7 (first through hole 8a has a shape that is not closed). Thus, the inconvenience described above can be prevented.

In joint sections 13a, 13b formed of bonding material 13, for example, when a high thermal conductivity of 100 W/(m·K) or more is not required, a sintered material or an adhesive containing resin may be used as bonding material 13. When bonding material 13 is a sintered material or an adhesive containing resin, the elasticity of joint section 13a and joint section 13b is reduced due to the resin. As a result, joint section 13a and joint section 13b with high reliability and long life can be obtained. Further, in joint section 13c that bonds semiconductor element 2 to first heat dissipation substrate 4, a plate-shaped bonding material 13 may be used, but a paste-like bonding material 13 may be used in order to improve productivity. Paste-like bonding material 13 may be disposed on the surface of first heat dissipation substrate 4, for example, by screen printing.

As shown in FIG. 4, a plating layer 12 may be provided on a surface in contact with bonding material 13 in electrode 3 of semiconductor element 2, terminal 7, second heat dissipation substrate 5, and the outer periphery of heat dissipation block 6. FIG. 4 is a partially-enlarged cross-sectional view showing a modification of semiconductor device 1 shown in FIG. 1 and FIG. 2. FIG. 4 corresponds to FIG. 2. Plating layer 12 may be any one selected from the group consisting of a nickel (Ni) plating layer, a silver (Ag) plating layer, and a tin (Sn) plating layer. The thickness of plating layer 12 is 0.001 mm or more and 0.002 mm or less. In FIG. 4, plating layer 12 is formed on the whole of the interface between joint section 13a and electrode 3 of semiconductor element 2, terminal 7, second heat dissipation substrate 5, and the outer periphery of heat dissipation block 6, but plating layer 12 may be provided partially at the interface between joint section 13a and electrode 3 of semiconductor element 2, terminal 7a, second heat dissipation substrate 5, and the outer periphery of heat dissipation block 6 and the interface between joint section 13b and first heat dissipation substrate 4, terminal 7b, and the outer periphery of heat dissipation block 6.

### <Method of Manufacturing Semiconductor Device>

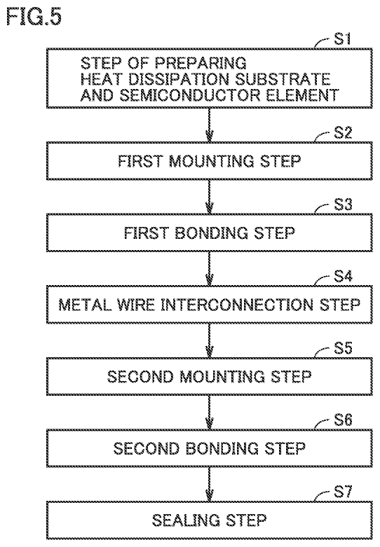

FIG. 5 is a flowchart illustrating a method of manufacturing semiconductor device 1 according to the first embodiment. A method of manufacturing semiconductor device 1 will be described below. As shown in FIG. 5, in the method of manufacturing semiconductor device 1, a step of preparing a heat dissipation substrate and a semiconductor element (S1) is performed. In this step (S1), members necessary in the steps described later, such as first heat dissipation substrate 4, second heat dissipation substrate 5, semiconductor element 2, heat dissipation block 6, terminal 7, and bonding material 13, are prepared.

Next, a first mounting step (S2) is performed. In this step (S2), semiconductor element 2 is mounted on a surface of first heat dissipation substrate 4 with bonding material 13 as a first bonding material interposed. Specifically, first, plate-shaped bonding material 13 corresponding to the size of the flat surface of semiconductor element 2 is disposed at a predetermined position in the surface of first heat dissipation substrate 4. Further, semiconductor element 2 is mounted on bonding material 13. A special jig for alignment and fixing may be used, if necessary, so that first heat dissipation substrate 4, bonding material 13, and semiconductor element 2 are not misaligned. The special jig is formed of, for example, a carbon material. The special jig has an opening for arranging first heat dissipation substrate 4, bonding material 13, and semiconductor element 2 so that these members are easily aligned (not shown).

Next, a first bonding step (S3) is performed. In this step (S3), semiconductor element 2 and first heat dissipation substrate 4 are bonded with bonding material 13 interposed. Specifically, first heat dissipation substrate 4 having bonding material 13 and semiconductor element 2 mounted thereon is put into a reflow device for heating and cooling. Subsequently, bonding material 13 is melted by heating by the reflow device. Subsequently, first heat dissipation substrate 4 having bonding material 13 and semiconductor element 2 mounted thereon is cooled. As a result, semiconductor element 2 and first heat dissipation substrate 4 are bonded by joint section 13c formed of the solidified bonding material 13. It is necessary to perform heating and cooling in accordance with a temperature profile corresponding to a material composition of the material of bonding material 13 (for example, solder, sintered material, or adhesive). When a special jig as described above is used, the special jig is also put into the reflow device together with the above first heat dissipation substrate 4, and heating and cooling is performed. An atmosphere in the reflow device for heating can be controlled by nitrogen, formic acid, or the like.

Next, a metal wire interconnection step (S4) is performed. In this step (S4), terminal 7c connected to the outside is connected to electrode 3 that is the control electrode of semiconductor element 2 by a wire bonding device through metal wire interconnection 14 (see FIG. 1).

Next, a second mounting step (S5) is performed. In this step (S5), heat dissipation block 6 and terminal 7a (see FIG. 1) are disposed on electrode 3 (see FIG. 2) of semiconductor element 2 with bonding material 13 as a second bonding material interposed. Bonding material 13 is a plate-shaped bonding material having a size corresponding to the size of electrode 3 of semiconductor element 2. Terminal 7a has first through hole 8a. Terminal 7a is aligned such that first through hole 8a is located on bonding material 13. Subsequently, second heat dissipation substrate 5 is mounted on heat dissipation block 6 mounted on electrode 3 of semiconductor element 2, with bonding material 13 as a third bonding material interposed. Further, heat dissipation block 6 and terminal 7b (see FIG. 1) are disposed on the surface of first heat dissipation substrate 4 with the plate-shaped bonding material 13 interposed. Terminal 7b has first through hole 8a. Terminal 7b is aligned such that first through hole 8a is located on bonding material 13. A special jig for alignment and fixing may be used, if necessary, so that bonding material 13 mounted on electrode 3 of semiconductor element 2, bonding material 13 mounted on the surface of first heat dissipation substrate 4, terminal 7a, and terminal 7b are not misaligned.

Next, a second bonding step (S6) is performed. In this step (S6), electrode 3 of semiconductor element 2, terminal 7a, and second heat dissipation substrate 5 are bonded with bonding material 13 interposed. First heat dissipation substrate 4 and terminal 7b are bonded similarly. Specifically, first heat dissipation substrate 4 having bonding material 13, terminal 7a, terminal 7b, and second heat dissipation substrate 5 mounted thereon is put into a reflow device for heating and cooling. Next, bonding material 13 is melted by heating in the reflow device. The heating temperature in this case is lower than the heating temperature in the first bonding step (S3). Subsequently, the melted bonding material 13 is cooled to bond semiconductor element 2, terminal 7a, and second heat dissipation substrate 5 and form joint section 13a. First heat dissipation substrate 4 and terminal 7b are bonded similarly to form joint section 13b. The heating and cooling is performed in accordance with a temperature profile corresponding to a material composition of the material of bonding material 13 (for example, solder, sintered material, and adhesive). The melting point of bonding material 13 melted in this step (S6) is lower than the melting point of bonding material 13 forming joint section 13c that is used in bonding of first heat dissipation substrate 4 and semiconductor element 2. This is to prevent melting of bonding material 13 that has already bonded first heat dissipation substrate 4 and semiconductor element 2 in the first bonding step (S3), in the heating in this step (S6).

Next, a sealing step (S7) is performed. In this step (S7), semiconductor element 2 is sealed by sealing resin 16 by transfer molding. Specifically, sealing resin 16 in the shape of a tablet and insulating heat dissipation sheet 15 (see FIG. 1) are prepared. Insulating heat dissipation sheet 15 is mounted in a mold of a device that performs transfer molding. Next, first heat dissipation substrate 4 to which semiconductor element 2, terminal 7a, terminal 7b, and terminal 7c are bonded, as well as second heat dissipation substrate 5 bonded to first heat dissipation substrate 4 are mounted on insulating heat dissipation sheet 15. Next, insulating heat dissipation sheet 15 is mounted on the bottom surface of second heat dissipation substrate 5. Subsequently, a mold including an upper die and a lower die is clamped to form a sealed interior space, and sealing resin 16 in the shape of a tablet is put into the device. Next, the inside of the mold is heated, whereby insulating heat dissipation sheet 15 adheres to each of first heat dissipation substrate 4 and second heat dissipation substrate 5, and simultaneously, semiconductor element 2, first heat dissipation substrate 4, second heat dissipation substrate 5, and terminal 7a, terminal 7b, and terminal 7c are sealed by the melted sealing resin 16, except parts of terminal 7a, terminal 7b, and terminal 7c. Next, a curing process is performed to cure sealing resin 16. In a case where terminal 7a, terminal 7b, and terminal 7c are formed from a lead frame, tie bars, resin, and the frame of the lead frame are cut off. Next, parts (tip ends) of terminal 7a, terminal 7b, and terminal 7c protruding from sealing resin 16 are bent by forming. Finally, whether the electrical characteristics as semiconductor device 1 are satisfied is inspected. In this way, semiconductor device 1 shown in FIG. 1 and FIG. 2 is produced.

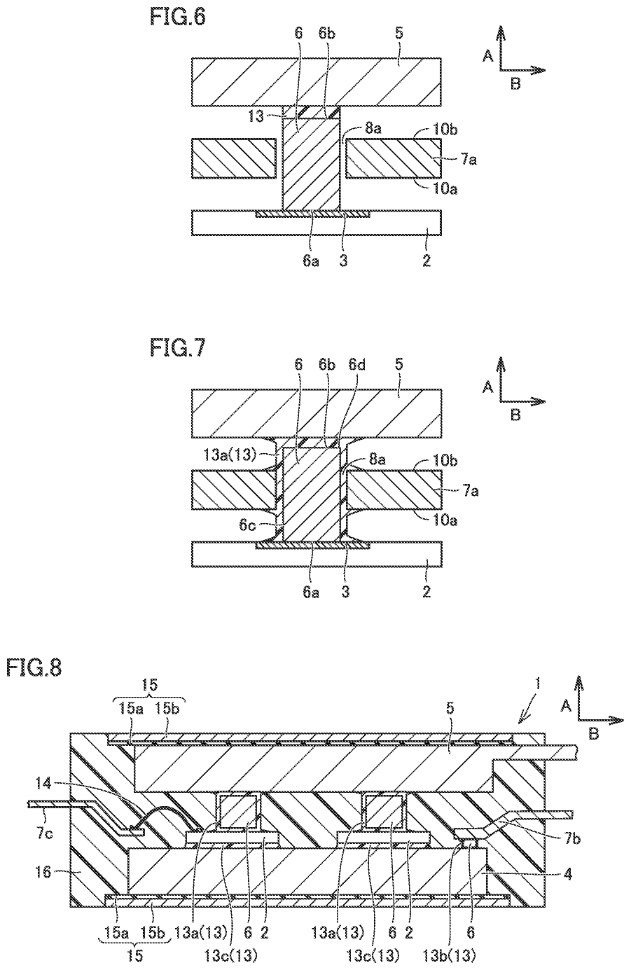

A modification of the method of manufacturing semiconductor device 1 will now be described. FIG. 6 is a partially-enlarged cross-sectional view of semiconductor device 1 before the second bonding step (S5). FIG. 7 is a partially-enlarged cross-sectional view of semiconductor device 1 after the second bonding step (S6). The modification of the method of manufacturing semiconductor device 1 described below basically includes steps similar to those of the method of manufacturing semiconductor device 1 shown in FIG. 5 but differs in the steps after the second mounting step (S5) shown in FIG. 5. A modification of the method of manufacturing semiconductor device 1 will be described below.

First of all, similar steps from the step (S1) to step (S4) shown in FIG. 5 are performed. Next, a second mounting step (S5) is performed. This step (S5) differs from the step (S5) shown in FIG. 5 in that heat dissipation block 6 is mounted directly on electrode 3 of semiconductor element 2 without bonding material 13 as a second bonding material interposed. In other words, after the second mounting step (S5), as shown in FIG. 6, bonding material 13 is mounted only on heat dissipation block 6.

In the next second bonding step (S6), bonding material 13 mounted on heat dissipation block 6 is melted during heating in the reflow device, and bonding material 13 wets and spreads toward electrode 3 of semiconductor element 2 so as to cover the outer periphery of heat dissipation block 6. Subsequently, the melted bonding material 13 is cooled, whereby, as shown in FIG. 7, electrode 3 of semiconductor element 2 is directly connected to first heat dissipation block main surface 6a of heat dissipation block 6, and joint section 13a is formed such that second heat dissipation block main surface 6b and heat dissipation block side surface 6c are covered with bonding material 13 as a third bonding material. In particular, in a case where bonding material 13 is solder, joint section 13a shown in FIG. 7 is easily formed because bonding material 13 wets and spreads by heating in the reflow device due to the wettability of the solder.

Second heat dissipation substrate 5 and heat dissipation block 6 are bonded with bonding material 13 interposed, but second heat dissipation block main surface 6b opposed to second heat dissipation substrate 5 may be in direct contact with second heat dissipation substrate 5 after cooling, under the weight of second heat dissipation substrate 5. In other words, heat dissipation block side surface 6c of heat dissipation block 6 and second heat dissipation substrate 5 are bonded by bonding material 13, and second heat dissipation block main surface 6b of heat dissipation block 6 and second heat dissipation substrate 5 may be in contact with each other. In order to suppress spread of cracking, it is preferable that corner 6d of heat dissipation block 6 is rounded or chamfered.

Subsequently, a sealing step (S6a) is performed in the same manner as the step (S7) shown in FIG. 5. Semiconductor device 1 shown in FIG. 7 can be obtained in this way.

### <Operation Effects>

Semiconductor device 1 according to the present disclosure includes semiconductor element 2, first heat dissipation substrate 4, second heat dissipation substrate 5, and heat dissipation block 6. Semiconductor element 2 has electrode 3. Semiconductor element 2 is mounted on first heat dissipation substrate 4. Heat dissipation block 6 is disposed so as to be opposed to electrode 3 of semiconductor element 2. Second heat dissipation substrate 5 is disposed on a side opposite to electrode 3 of semiconductor element 2 as viewed from heat dissipation block 6. Bonding material 13 covers heat dissipation block side surface 6c that is the side surface of heat dissipation block 6 and is in contact with electrode 3 of semiconductor element 2 and second heat dissipation substrate 5.

In this configuration, even if cracking due to stress or distortion produced in bonding material 13 occurs during operation of semiconductor device 1, heat dissipation block 6 with a strength higher than bonding material 13 prevents spread of cracking produced in bonding material 13, thereby significantly reducing the possibility of disconnection during operation of semiconductor device 1. Further, since bonding material 13 is disposed so as to cover heat dissipation block side surface 6c rather than a part of heat dissipation block 6, the strength is improved by the additional amount of bonding material 13. As a result, semiconductor device 1 with high reliability and long life can be obtained. The effects described above are achieved not only in joint section 13a but also in joint section 13b.

The above semiconductor device 1 includes terminal 7a having first through hole 8a. Terminal 7a has first terminal main surface 10a and second terminal main surface 10b. First terminal main surface 10a is opposed to electrode 3 of semiconductor element 2. Second terminal main surface 10b is opposite to first terminal main surface 10a. First through hole 8a is formed so as to extend from first terminal main surface 10a and reach second terminal main surface 10b. Terminal 7 is disposed between electrode 3 of semiconductor element 2 and second heat dissipation substrate 5 such that heat dissipation block 6 is disposed in the inside of first through hole 8a. Bonding material 13 is in contact with terminal 7.

In this configuration, semiconductor device 1 can be electrically connected to a circuit board or another semiconductor device through terminal 7. Further, even if cracking occurs in bonding material 13 at the interface between bonding material 13 and first through hole 8a, heat dissipation block 6 prevents spread of cracking, thereby significantly reducing the possibility of disconnection during operation of semiconductor device 1.

In the above semiconductor device 1, as shown in FIG. 2, bonding material 13 extends from the inside of first through hole 8a onto first terminal main surface 10a and onto second terminal main surface 10b. In this configuration, joint section 13a formed of bonding material 13 is shaped like a rivet, and the area of bonding interface between the bonding material 13 and terminal 7 is increased. Thus, the bonding strength of joint section 13a is increased. The effects described above are achieved not only in joint section 13a but also in joint section 13b.

The material of bonding material 13 used in the above semiconductor device 1 may contain any one selected from the group consisting of solder, sintered material, and adhesive. In this configuration, in a case where bonding material 13 is solder, bonding material 13 adheres to the side surface of first through hole 8a of terminal 7 because of the wettability of the solder, thereby ensuring the bonding strength between joint section 13a and terminal 7.

In a case where bonding material 13 is a sintered material using fine particles of metal including silver (Ag) or copper (Cu), joint section 13a with high heat dissipation can be obtained. Further, since first through hole 8a has a shape that is not closed, the solvent contained in the sintered material can be volatilized well and the solvent can be removed from joint section 13a in the heating step for forming joint section 13a. As a result, first through hole 8a can be covered with bonding material 13 reliably, and formation of voids in joint section 13a can be prevented. In a case where bonding material 13 is a sintered material or an adhesive containing resin, the elasticity of joint section 13a and joint section 13b can be reduced. As a result, semiconductor device 1 with high reliability and long life can be obtained.

In the above semiconductor device 1, any one selected from the group consisting of electrode 3 of semiconductor element 2, terminal 7, second heat dissipation substrate 5, and heat dissipation block 6 includes plating layer 12 formed in a region in contact with bonding material 13. In this configuration, the adhesion to bonding material 13 can be improved at the interface with each of joint section 13a and joint section 13b, thereby preventing occurrence of a not-bonded section. As a result, the bonding strength at joint sections 13a, 13b can be ensured. In particular, in a case where bonding material 13 is solder, plating layer 12 improves the wettability of the solder. For example, when the side surface of first through hole 8a has a recess 9 as in the fifth and sixth embodiments described later, bonding material 13 can adhere well to recess 9.

In the above semiconductor device 1, plating layer 12 includes at least one selected from the group consisting of nickel, silver, gold, and tin as a main component. In a case where solder is used as bonding material 13, the formation of plating layer 12 can promote wetting of the solder. Further, in a case where a sintered material is used as bonding material 13, the bonding between the sintered material and plating layer 12 can be promoted. In this way, the bonding strength between bonding material 13 and a member such as electrode 3 having plating layer 12 formed thereon can be improved.

In the above semiconductor device 1, first heat dissipation substrate 4 and second heat dissipation substrate 5 include aluminum or copper as a main component. In this case, the heat dissipation of semiconductor device 1 can be improved, and semiconductor element 2 can be cooled effectively. Thus, deterioration of the characteristics (for example, switching loss, etc.) of semiconductor element 2 can be suppressed.

In the above semiconductor device 1, first heat dissipation substrate 4 and second heat dissipation substrate 5 each have insulating heat dissipation sheet 15 connected to a surface opposite to the surfaces facing each other. Insulating heat dissipation sheet 15 includes insulating layer 15a and metal layer 15b. Metal layer 15b is laminated on insulating layer 15a. In this case, a cooler including radiating fins can be connected with insulating heat dissipation sheet 15 interposed. Thus, the cooling performance of semiconductor device 1 can be improved.

The above semiconductor device 1 includes sealing resin 16 that covers semiconductor element 2, first heat dissipation substrate 4, and second heat dissipation substrate 5. In this case, sealing resin 16 ensures the insulation of semiconductor element 2 and the like and provides protection against external impact.

In the above semiconductor device 1, semiconductor element 2 is an insulated gate bipolar transistor. In this case, the above semiconductor device 1 can be applied to a power conversion device or the like.

In the above semiconductor device 1, semiconductor element 2 includes a wide-bandgap semiconductor. In this case, semiconductor device 1 with higher efficiency and compatible with higher temperatures can be implemented, compared with semiconductor element 2 using silicon as a base material.

The method of manufacturing semiconductor device 1 according to the present disclosure includes a preparing step (S1), a step of mounting semiconductor element 2 (S2), a step of bonding semiconductor element 2 (S3), a step of connecting metal wire interconnection 14 (S4), a step of mounting second heat dissipation substrate 5 (S5), a step of bonding second heat dissipation substrate 5 (S6), and a step of performing sealing (S7). In the preparing step (S1), first heat dissipation substrate 4 and semiconductor element 2 having electrode 3 are prepared. In the step of mounting semiconductor element 2 (S2), semiconductor element 2 is mounted on first heat dissipation substrate 4 with bonding material 13 as a first bonding material interposed. In the step of bonding the semiconductor element (S3), bonding material 13 is heated to bond semiconductor element 2 to first heat dissipation substrate 4 with bonding material 13 interposed. In the step of connecting metal wire interconnection 14 (S4), metal wire interconnection 14 is connected to electrode 3 of semiconductor element 2. In the step of mounting second heat dissipation substrate 5 (S5), heat dissipation block 6 is mounted on electrode 3 of semiconductor element 2 with bonding material 13 as a second bonding material interposed, and second heat dissipation substrate 5 is further mounted on heat dissipation block 6 with bonding material 13 as a third bonding material interposed. In the step of bonding second heat dissipation substrate 5 (S6), bonding material 13 serving as the second bonding material and the third bonding material is heated so that bonding material 13 covers the side surface of heat dissipation block 6 and bonds electrode 3 of semiconductor element 2 to second heat dissipation substrate 5. In the step of performing sealing (S7), semiconductor element 2 is sealed with sealing resin 16 by transfer molding. Semiconductor device 1 according to the present disclosure can be obtained in this way.

### Second Embodiment

### <Configuration of Semiconductor Device>

FIG. 8 is a cross-sectional view of semiconductor device 1 according to a second embodiment. FIG. 8 corresponds to FIG. 1. Semiconductor device 1 shown in FIG. 8 basically has a configuration similar to semiconductor device 1 shown in FIG. 1 and FIG. 2 but differs in that terminal 7a having first through hole 8a does not exist and a part of second heat dissipation substrate 5 extends from the surface of sealing resin 16 to the outside so that it functions as a terminal connectible to an external device in the outside.

### <Operation Effects>

In this configuration, effects similar to those of semiconductor device 1 according to the first embodiment can be achieved, and in addition, the member that is terminal 7a having first through hole 8a can be eliminated. Thus, the materials necessary for this semiconductor device 1 and the costs involved with the production are reduced, and the assembly of semiconductor device 1 can be simplified. A part of terminal 7b and a part of second heat dissipation substrate 5 extending from the surface of sealing resin 16 to the outside are spaced apart from each other on the outside of sealing resin 16 so that a spatial distance therebetween can be ensured as much as possible.

### <Configuration of Modification>

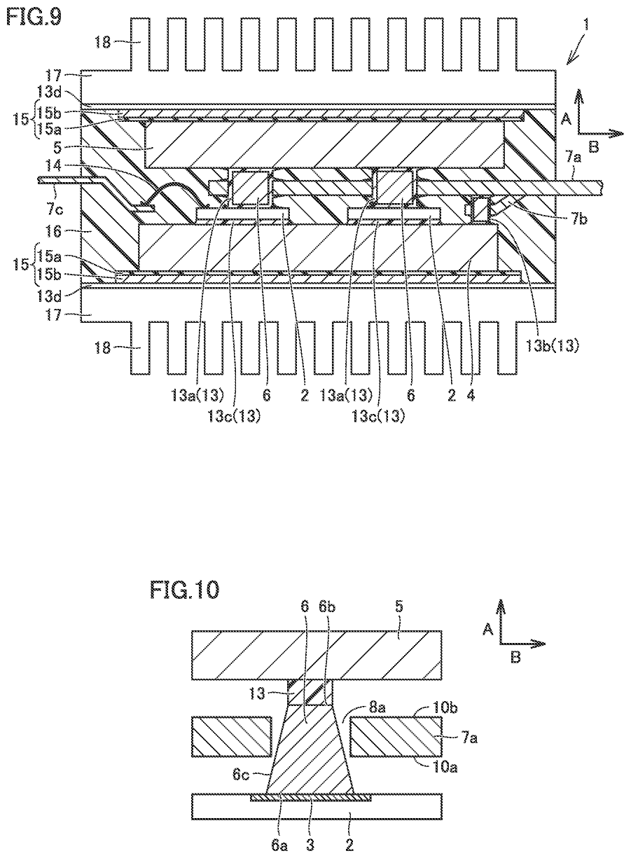

FIG. 9 is a cross-sectional view of a modification of semiconductor device 1 according to the second embodiment. FIG. 9 corresponds to FIG. 1. Semiconductor device 1 shown in FIG. 9 basically has a configuration similar to semiconductor device 1 shown in FIG. 1 and FIG. 2 but differs in that a cooler 17 is connected to metal layer 15b of insulating heat dissipation sheet 15. Specifically, coolers 17 are connected to metal layers 15b of two insulating heat dissipation sheets 15 exposed from sealing resin 16, with respective joint sections 13d interposed.

When the operating temperature of semiconductor element 2 exceeds a rating value, the switching performance of semiconductor element 2 deteriorates and, in the worst case, thermal runaway occurs to cause damage to semiconductor element 2. Thus, in addition to first heat dissipation substrate 4 and second heat dissipation substrate 5 with high thermal conductivity, cooler 17 is further provided with insulating heat dissipation sheet 15 interposed, whereby heat dissipation and cooling performance can be improved in semiconductor device 1. For example, a material selected from the group consisting of bonding material 13 described above, thermal grease, and thermal interface material (TIM) can be disposed on the lower surface of insulating heat dissipation sheet 15, and first heat dissipation substrate 4 and second heat dissipation substrate each can be connected to the cooler by joint section 13d made of the above material.

The material of cooler 17 is, for example, a metal with high thermal conductivity including aluminum (Al). Cooler 17 has a plurality of radiating fins 18. In cooler 17, a plurality of radiating fins 18 are formed so as to protrude from a base connected to insulating heat dissipation sheet 15. The cooling method of cooler 17 may be air cooling or water cooling. Further, joint section 13d is not necessarily formed, and first heat dissipation substrate 4 and cooler 17, or second heat dissipation substrate 5 and cooler 17 may be integrated. In this case, since first heat dissipation substrate 4 and second heat dissipation substrate 5 are each integrated with cooler 17, joint section 13d is not necessary. Thus, there is no interface resulting from the presence of joint section 13d, so that thermal resistance at the interface can be eliminated. As a result, heat dissipation from heating semiconductor element 2 and cooling performance are improved in semiconductor device 1. In a case where first heat dissipation substrate 4 and cooler 17, or second heat dissipation substrate 5 and cooler 17 are integrated, insulating layer 15a in the shape of a flat film is provided between cooler 17 and each of first heat dissipation substrate 4 and second heat dissipation substrate 5. The material forming insulating layer 15a may be an inorganic material selected from the group consisting of alumina (Al₂O₃), aluminum nitride (AlN), silicon nitride (Si₃N₄), silicon dioxide (SiO₂), and boron nitride (BN), or an organic material selected from the group consisting of epoxy resin, polyimide resin, acrylic resin, and polyphenylenesulfide (PPS) resin.

### <Operation Effects>

The above semiconductor device 1 may include cooler 17 connected to first heat dissipation substrate 4 or second heat dissipation substrate 5 with insulating heat dissipation sheet 15 interposed. In this configuration, heat dissipation from heating semiconductor element 2 and cooling performance can be improved in semiconductor device 1.

The above semiconductor device 1 may include cooler 17 connected to first heat dissipation substrate 4 or second heat dissipation substrate 5. Specifically, semiconductor device 1 may include cooler 17 connected directly to first heat dissipation substrate 4 or second heat dissipation substrate 5 without insulating heat dissipation sheet 15 interposed. In this configuration, expensive insulating heat dissipation sheet 15 is unnecessary in production of semiconductor device 1, and therefore the production costs of semiconductor device 1 can be reduced.

### Third Embodiment

### <Configuration of Semiconductor Device>

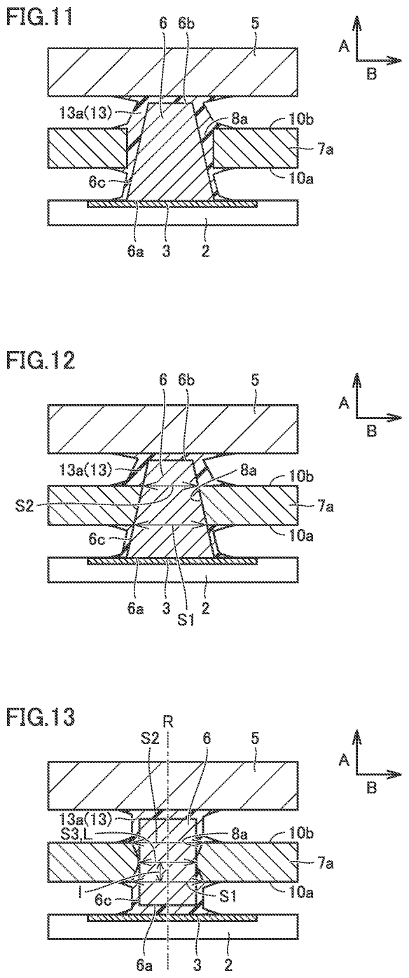

FIG. 10 is a partially-enlarged cross-sectional view of semiconductor device 1 according to a third embodiment before melting of bonding material 13. FIG. 11 is a partially-enlarged cross-sectional view of semiconductor device 1 according to the third embodiment after cooling of bonding material 13. FIG. 11 corresponds to FIG. 2. FIG. 12 is a partially-enlarged cross-sectional view in a modification of semiconductor device 1 according to the third embodiment. Semiconductor device 1 shown in FIG. 11 basically has a configuration similar to semiconductor device 1 shown in FIG. 1 and FIG. 2 but differs from semiconductor device 1 shown in FIG. 1 and FIG. 2 in that the shape of heat dissipation block 6 is a shape expanding downward and in that heat dissipation block 6 is in direct contact with electrode 3 of semiconductor element 2. Specifically, heat dissipation block 6 is shaped such that the surface area of first heat dissipation block main surface 6a is larger than the surface area of second heat dissipation block main surface 6b. The extending direction of heat dissipation block side surface 6c is inclined relative to first heat dissipation block main surface 6a. Heat dissipation block side surface 6c is inclined so as to face second heat dissipation substrate 5. Further, first heat dissipation block main surface 6a of heat dissipation block 6 is in direct contact with electrode 3 of semiconductor element 2. Joint section 13a formed of bonding material 13 extends from on heat dissipation block side surface 6c onto electrode 3 of semiconductor element 2.

As a method of manufacturing the semiconductor device shown in FIG. 11, a modification of the method of manufacturing semiconductor device 1 according to the first embodiment may be performed. In this case, first of all, the step (S1) to step (S4) shown in FIG. 5 are performed. Subsequently, as shown in FIG. 10, in the second mounting step (S5), heat dissipation block 6 is mounted on electrode 3 of semiconductor element 2 without bonding material 13 as a second bonding material interposed. Further, bonding material 13 as a third bonding material is mounted on second heat dissipation block main surface 6b. Subsequently, in the second bonding step (S6), heating and cooling by a reflow device is performed, resulting in a structure shown in FIG. 11. Specifically, first heat dissipation block main surface 6a is directly connected to electrode 3 of semiconductor element 2. Further, second heat dissipation block main surface 6b and heat dissipation block side surface 6c are covered with bonding material 13, and joint section 13a is formed in which a part of bonding material 13 is in contact with electrode 3 of semiconductor element 2, terminal 7a, and second heat dissipation substrate 5. Subsequently, the sealing step (S7) shown in FIG. 5 is performed, resulting in a semiconductor device according to the third embodiment.

### <Operation Effects>

In the above semiconductor device 1, heat dissipation block 6 has first heat dissipation block main surface 6a facing electrode 3 of semiconductor element 2, and second heat dissipation block main surface 6b opposite to first heat dissipation block main surface 6a. A first surface area that is the surface area of first heat dissipation block main surface 6a is larger than a second surface area that is the surface area of second heat dissipation block main surface 6b.

In this configuration, since heat dissipation block 6 has a shape expanding downward, the center of gravity of heat dissipation block 6 is located at a relatively lower side (electrode 3 side) during assembly of semiconductor device 1. Further, since the surface area of first heat dissipation block main surface 6a (the surface mounted on electrode 3) is larger than the surface area of second heat dissipation block main surface 6b, heat dissipation block 6 can be mounted in a self-standing manner on electrode 3 of semiconductor element 2. Thus, the stability and the ease of operation in mounting heat dissipation block 6 on electrode 3 of semiconductor element 2 are improved. Heat dissipation block 6 disposed in the inside of first through hole 8a of terminal 7b may also have a similar shape.

As a modification of the semiconductor device according to the third embodiment, as shown in FIG. 12, the shape of first through hole 8a of terminal 7a may also have a shape expanding downward corresponding to the shape expanding downward of heat dissipation block 6. Specifically, terminal 7a has a first opening area S1 of first through hole 8a on first terminal main surface 10a, and a second opening area S2 of first through hole 8a on second terminal main surface 10b. First through hole 8a has such a shape that second opening area S2 is smaller than first opening area S1. This configuration facilitates the alignment of heat dissipation block 6. The shape of first through hole 8a in terminal 7b may also have a shape as shown in FIG. 12.

### Fourth Embodiment

### <Configuration of Semiconductor Device>

FIG. 13 is a partially-enlarged cross-sectional view of semiconductor device 1 according to a fourth embodiment. FIG. 13 corresponds to FIG. 2. Semiconductor device 1 shown in FIG. 13 basically has a configuration similar to semiconductor device 1 shown in FIG. 1 and FIG. 2 but differs from semiconductor device 1 shown in FIG. 1 and FIG. 2 in the shape of first through hole 8a of terminal 7a. Specifically, in semiconductor device 1 shown in FIG. 13, in through hole 8a, first opening area S1 and second opening area S2 are larger than a smallest hole area S3 in a narrow region L located at an intermediate region in the extending direction of first through hole 8a. Here, smallest hole area S3 is the area in the radial direction of first through hole 8a in the narrow region L. Smallest hole area S3 is the smallest area of the area in the radial direction in the inside of first through hole 8a. First opening area S1 is the area of first through hole 8a on first terminal main surface 10a. Second opening area S2 is the area of first through hole 8a on second terminal main surface 10b.

The narrow region L that is a first region is a region in the inside of through first through hole 8a and away from first terminal main surface 10a by a first distance 1 in the A direction that is a direction along the center axis R of first through hole 8a. The narrow region L has smallest hole area S3 that is the smallest hole area in first through hole 8a. The side surface of first through hole 8a is inclined relative to first terminal main surface 10a and second terminal main surface 10b. In other words, the side surface of first through hole 8a intersects first terminal main surface 10a and second terminal main surface 10b at an angle such that the hole area gradually increases from the narrow region L toward each of first terminal main surface 10a and second terminal main surface 10b. The shape of first through hole 8a in terminal 7b may also have a shape as shown in FIG. 13.

### <Operation Effects>

In the above semiconductor device 1, first through hole 8a may have the narrow region L as a first region in which the area in the radial direction of first through hole 8a is smallest. First opening area S1 of first through hole 8a on first terminal main surface 10a and second opening area S2 of first through hole 8a on second terminal main surface 10b are larger than smallest hole area S3 that is the area in the narrow region L.

In this configuration, when heat dissipation block 6 is mounted on electrode 3 of semiconductor element 2, heat dissipation block 6 can be aligned at the narrow region L of first through hole 8a. Thus, the ease of assembly in the manufacturing process of semiconductor device 1 can be improved.

### <Configuration of Modification>

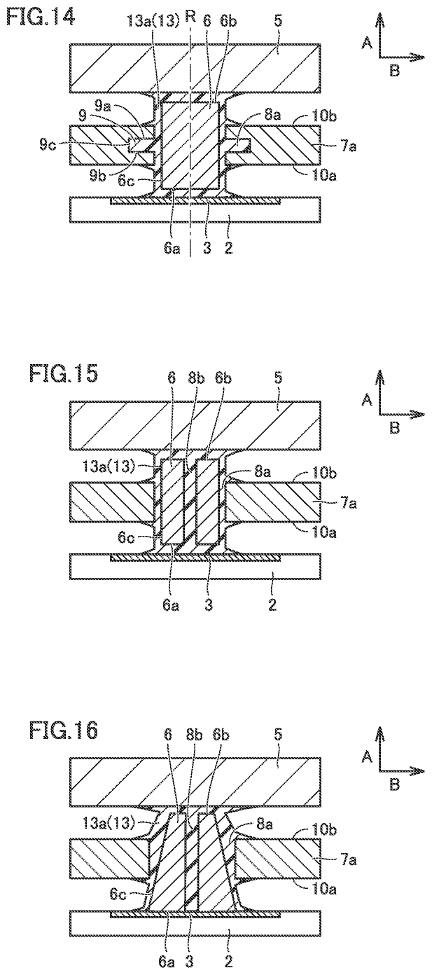

FIG. 14 is a partially-enlarged cross-sectional view in a modification of semiconductor device 1 according to the fourth embodiment. FIG. 14 corresponds to FIG. 13. Semiconductor device 1 shown in FIG. 14 basically has a configuration similar to semiconductor device 1 shown in FIG. 13 but differs from the semiconductor device shown in FIG. 1 and FIG. 2 in the shape of first through hole 8a of terminal 7a. Specifically, a recess 9 is formed in the inner peripheral surface of first through hole 8a.

Recess 9 is a recessed step portion and includes a first step surface 9a, a second step surface 9b, and a third step surface 9c. First step surface 9a and second step surface 9b each extend to intersect the side surface of first through hole 8a. First step surface 9a and second step surface 9b face each other in parallel. First step surface 9a and second step surface 9b extend in a direction normal to the side surface of first through hole 8a. Third step surface 9c extends in a direction along the side surface of first through hole 8a. The extending direction of third step surface 9c is, for example, parallel to the extending direction of the side surface of first through hole 8a. Third step surface 9c intersects each of first step surface 9a and second step surface 9b. As viewed from the center axis R of first through hole 8a, third step surface 9c is disposed at a position farthest from the center axis R in recess 9. Such a recess 9 is formed in the inner peripheral surface of first through hole 8a by a chemical process such as etching or a physical process such as machining. Recess 9 is formed to extend in the circumferential direction around the center axis R in the inner peripheral surface of first through hole 8a. Recess 9 may be formed all around the inner peripheral surface of first through hole 8a or may be formed only at a part in the circumferential direction of the inner peripheral surface.

Bonding material 13 forming joint section 13a is disposed so as to cover the outer periphery of heat dissipation block 6 and fill the inside of first through hole 8a including the inside of recess 9. Bonding material 13 is connected to electrode 3 of semiconductor element 2, terminal 7a, and second heat dissipation substrate 5.

### <Operation Effects>

In the above semiconductor device 1, terminal 7 has recess 9 formed in the inner peripheral surface of first through hole 8a. In this configuration, the provision of recess 9 in the inner peripheral surface of first through hole 8a increases the joint area between terminal 7a and joint section 13a to achieve an anchor effect. As a result, the bonding strength of joint section 13a is significantly improved, and semiconductor device 1 with high reliability and long life can be obtained. The anchor effect can be achieved by at least one recess 9. It is preferable to provide a plurality of recesses 9 in order to increase the anchor effect. Further, in a case where plating layer 12 as shown in FIG. 4 is provided on the side surface including recess 9 of first through hole 8a, even a minute portion of recess 9 is filled with bonding material 13, which is effective in improving the bonding strength.

### Fifth Embodiment

### <Configuration of Semiconductor Device>

FIG. 15 is a partially-enlarged cross-sectional view of semiconductor device 1 according to a fifth embodiment. FIG. 15 corresponds to FIG. 2. Semiconductor device 1 shown in FIG. 15 basically has a configuration similar to semiconductor device 1 shown in FIG. 1 and FIG. 2 but differs from semiconductor device 1 shown in FIG. 1 and FIG. 2 in the shape of heat dissipation block 6. Specifically, in the semiconductor device shown in FIG. 15, heat dissipation block 6 has a second through hole 8b penetrating from first heat dissipation block main surface 6a to second heat dissipation block main surface 6b. Joint section 13a is formed such that not only the outer periphery of heat dissipation block 6 but also the inside of second through hole 8b is filled with bonding material 13.

As shown in FIG. 16 to FIG. 18, the configuration of heat dissipation block 6 having second through hole 8b can be freely combined with a shape of heat dissipation block 6 and a shape of first through hole 8a of terminal 7a different from the configuration shown in FIG. 15. FIG. 16 to FIG. 18 are partially-enlarged cross-sectional views showing a modification of the semiconductor device according to the fifth embodiment. Semiconductor device 1 shown in FIG. 16 to FIG. 18 basically has a configuration similar to the semiconductor device shown in FIG. 15 but differs from the semiconductor device shown in FIG. 15 in the shape of heat dissipation block 6 or the shape of first through hole 8a.

For example, as shown in FIG. 16, second through hole 8b may be formed in heat dissipation block 6 having a shape expanding downward. The configuration of joint section 13a and terminal 7a in the configuration shown in FIG. 16 is similar to the configuration of joint section 13a and terminal 7a in the semiconductor device shown in FIG. 11.

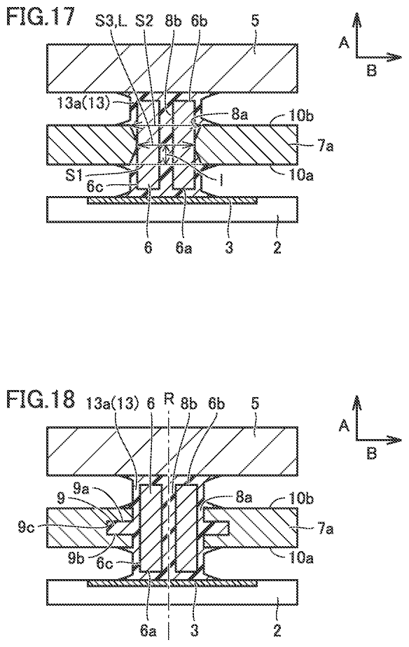

Further, as shown in FIG. 17, the shape of first through hole 8a in which heat dissipation block 6 having second through hole 8b is disposed may be such that first opening area S1 and second opening area S2 are larger than smallest hole area S3 in the narrow region L. Further, the side surface of first through hole 8a may intersect first terminal main surface 10a and second terminal main surface 10b at an angle such that the hole area gradually increases from the narrow region L toward each of first terminal main surface 10a and second terminal main surface 10b. The configuration of joint section 13a and terminal 7a in the configuration shown in FIG. 16 is similar to the configuration of joint section 13a and terminal 7a in the semiconductor device shown in FIG. 13.

Further, as shown in FIG. 18, recess 9 may be provided in the inner peripheral surface of first through hole 8a in which heat dissipation block 6 having second through hole 8b is disposed. The configuration of joint section 13a and terminal 7a in the configuration shown in FIG. 18 is similar to the configuration of joint section 13a and terminal 7a in the semiconductor device shown in FIG. 14.

### <Operation Effects>

In the above semiconductor device 1, heat dissipation block 6 has second through hole 8b penetrating from first heat dissipation block main surface 6a to second heat dissipation block main surface 6b.

In this configuration, joint section 13a can be formed such that not only the outer periphery of heat dissipation block 6 but also the inside of second through hole 8b is filled with bonding material 13. Thus, the bonding strength between electrode 3 of semiconductor element 2 and second heat dissipation substrate 5 is improved. As a result, semiconductor device 1 with high reliability and long life can be obtained.

### Sixth Embodiment

In the present embodiment, the semiconductor device according to the foregoing first to fifth embodiments is applied to a power conversion device.

Although the present disclosure is not limited to any specific power conversion device, a case where the present disclosure is applied to a three-phase inverter will be described as a sixth embodiment.

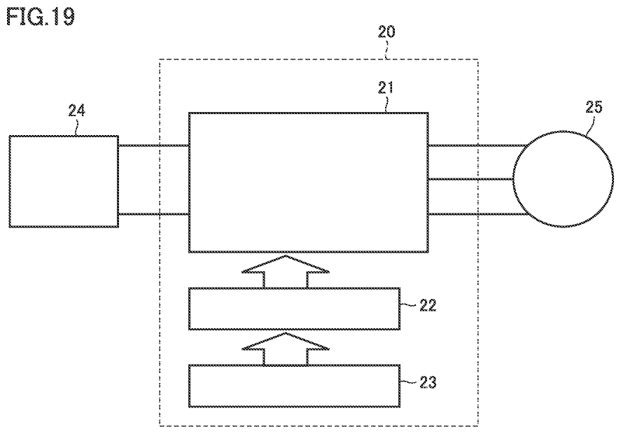

FIG. 19 is a block diagram showing a configuration of a power conversion system in which a power conversion device according to the present embodiment is applied.

The power conversion system shown in FIG. 19 includes a power source 24, a power conversion device 20, and a load 25. Power source 24 is a DC power source to supply a DC power to power conversion device 20. Power source 24 can be configured with a variety of sources and can be configured with, for example, a DC system, a solar battery, or a storage battery or may be configured with a rectifying circuit or an AC/DC converter connected to an AC system. Power source 24 may be configured with a DC/DC converter that converts a DC power output from a DC system into a prescribed power.

Power conversion device 20 is a three-phase inverter connected between power source 24 and load 25 to convert an input DC power supplied from power source 24 into an AC power and supply the AC power to load 25. As shown in FIG. 19, power conversion device 20 includes a main conversion circuit 21 to convert a DC power into an AC power and output the AC power, a drive circuit 22 to output a drive signal for driving each switching element in main conversion circuit 21, and a control circuit 23 to output a control signal for controlling drive circuit 22 to drive circuit 22.

Load 25 is a three-phase motor driven by an AC power supplied from power conversion device 20. Load 25 is a motor not limited to any particular applications and installed in a variety of electrical instruments and used as, for example, a motor for hybrid vehicles, electric vehicles, railroad vehicles, elevators, or air conditioners. The detail of power conversion device 20 will be described below. Main conversion circuit 21 includes switching elements and freewheeling diodes (not shown), and the switching elements perform switching to convert a DC power supplied from power source 24 into an AC power to be supplied to load 25. There are a variety of circuit configurations of main conversion circuit 21. Main conversion circuit 21 according to the present embodiment may be a two-level three-phase full bridge circuit and include six switching elements and six freewheeling diodes connected in anti-parallel with the respective switching elements. Semiconductor device 1 according to any one of the foregoing first to fifth embodiments is applied to each switching element in main conversion circuit 21. Six switching elements are connected two by two in series to form upper and lower arms, and the upper and lower arms constitute each phase (U phase, V phase, W phase) of a full-bridge circuit. The output terminals of the upper and lower arms, that is, three output terminals of main conversion circuit 21 are connected to load 25.

Drive circuit 22 generates a drive signal for driving a switching element in main conversion circuit 21 and supplies the drive signal to the control electrode of the switching element of main conversion circuit 21. Specifically, a drive signal to turn on a switching element and a drive signal to turn off a switching element are output to the control electrode of each switching element, in accordance with the control signal from control circuit 23 described later. When the switching element is kept ON, the drive signal is a voltage signal (ON signal) equal to or higher than a threshold voltage of the switching element. When the switching element is kept OFF, the drive signal is a voltage signal (OFF signal) equal to or lower than a threshold voltage of the switching element.

Control circuit 23 controls the switching elements of main conversion circuit 21 such that a desired power is supplied to load 25. Specifically, the time in which each switching element of main conversion circuit 21 is to be turned on (ON time) is calculated based on a power to be supplied to load 25. For example, main conversion circuit 21 can be controlled by PWM control that modulates the ON time of switching elements in accordance with the voltage to be output. A control command (control signal) is output to drive circuit 22 such that an ON signal is output to a switching element to be turned ON and an OFF signal is output to a switching element to be turned OFF at each point of time. Drive circuit 22 outputs an ON signal or an OFF signal as a drive signal to the control electrode of each switching element, in accordance with the control signal.

In the power conversion device according to the present embodiment, since the semiconductor device according to any one of the first to fifth embodiments is applied as a switching element in main conversion circuit 21, a power conversion device with high reliability and long life can be implemented.

In the present embodiment, a two-level power conversion device has been described. However, the present embodiment is not limited thereto and can be applied to a variety of power conversion devices. In the present embodiment, a two-level power conversion device has been described, but the first to fifth embodiments may be applied to a three-level or multi-level power conversion device, or to a single-phase inverter when a power is supplied to a single-phase load. When a power is supplied to a DC load or the like, the present disclosure can also be applied to a DC/DC converter or an AC/DC converter.

The power conversion device to which the present disclosure is applied is not limited to the case where the load is a motor, and may be used as a power supply device for electric discharge machines or laser machines, or induction heating cookers or wireless charging systems, or may be used as a power conditioner for photovoltaic systems or power storage systems.

Although embodiments of the present disclosure have been described above, embodiments disclosed here should be understood as being illustrative rather than being limitative in all respects. The scope of the present disclosure is shown by the claims, and all equivalents to the claims and modifications within the scope of the claims are intended to be embraced.

What is claimed is:

1. A semiconductor device comprising:
a semiconductor element having an electrode;
a first heat dissipation substrate having the semiconductor element mounted thereon;
a heat dissipation block disposed to be opposed to the electrode;
a second heat dissipation substrate disposed on a side opposite to the electrode as viewed from the heat dissipation block; and
a bonding material covering a side surface of the heat dissipation block and in contact with the electrode of the semiconductor element and the second heat dissipation substrate.

2. The semiconductor device according to claim 1, wherein
the semiconductor device includes a terminal having a first through hole,
the terminal has
a first terminal main surface facing the electrode of the semiconductor element, and
a second terminal main surface opposite to the first terminal main surface,
the first through hole is formed to extend from the first terminal main surface and reach the second terminal main surface,
the terminal is disposed between the electrode of the semiconductor element and the second heat dissipation substrate such that the heat dissipation block is disposed inside of the first through hole, and
the bonding material is in contact with the terminal.

3. The semiconductor device according to claim 2, wherein the bonding material extends from inside of the first through hole onto the first terminal main surface and onto the second terminal main surface.

4. The semiconductor device according to claim 2, wherein the first through hole has a recess formed in an inner peripheral surface of the first through hole.

5. The semiconductor device according to claim 2, wherein
the first through hole has a first region in which an area in a radial direction of the first through hole is smallest, and
a first opening area of the first through hole on the first terminal main surface and a second opening area of the first through hole on the second terminal main surface are larger than the area in the first region.

6. The semiconductor device according to claim 1, wherein
the heat dissipation block has
a first heat dissipation block main surface facing the electrode of the semiconductor element, and
a second heat dissipation block main surface opposite to the first heat dissipation block main surface, and
a first surface area of the first heat dissipation block main surface is larger than a second surface area of the second heat dissipation block main surface.

7. The semiconductor device according to claim 1, wherein
the heat dissipation block has
a first heat dissipation block main surface facing the electrode of the semiconductor element, and
a second heat dissipation block main surface opposite to the first heat dissipation block main surface, and
the heat dissipation block further has a second through hole formed to extend from the first heat dissipation block main surface and reach the second heat dissipation block main surface.

8. The semiconductor device according to claim 1, wherein a material forming the bonding material includes any one selected from the group consisting of solder, sintered material, and adhesive.

9. The semiconductor device according to claim 2, wherein any one selected from the group consisting of the electrode, the terminal, the second heat dissipation substrate, and the heat dissipation block includes a plating layer formed in a region in contact with the bonding material.

10. The semiconductor device according to claim 9, wherein the plating layer includes at least one selected from the group consisting of nickel, silver, gold, and tin as a main component.

11. The semiconductor device according to claim 1, wherein the first heat dissipation substrate and the second heat dissipation substrate include aluminum or copper as a main component.

12. The semiconductor device according to claim 1, wherein
the first heat dissipation substrate and the second heat dissipation substrate each have an insulating heat dissipation sheet connected to a surface opposite to surfaces facing each other, and
the insulating heat dissipation sheet includes
an insulating layer and
a metal layer laminated on the insulating layer.

13. The semiconductor device according to claim 12, further comprising a cooler connected to the first heat dissipation substrate or the second heat dissipation substrate with the insulating heat dissipation sheet interposed.

14. The semiconductor device according to claim 1, further comprising a cooler connected to the first heat dissipation substrate or the second heat dissipation substrate.

15. The semiconductor device according to claim 1, further comprising a sealing resin covering the semiconductor element, the first heat dissipation substrate, and the second heat dissipation substrate.

16. The semiconductor device according to claim 1, wherein the semiconductor element is an insulated gate bipolar transistor.

17. The semiconductor device according to claim 1, wherein the semiconductor element includes a wide-bandgap semiconductor.

18. A power conversion device comprising:
a main conversion circuit having the semiconductor device according to claim 1, the main conversion circuit converting input power and outputting the converted power;
a drive circuit to output a drive signal for driving the semiconductor device to the semiconductor device; and
a control circuit to output a control signal for controlling the drive circuit to the drive circuit.

19. A method of manufacturing a semiconductor device, the method comprising:
preparing a first heat dissipation substrate, a second heat dissipation substrate, a heat dissipation block, and a semiconductor element having an electrode;
mounting the semiconductor element on the first heat dissipation substrate with a first bonding material interposed;
heating the first bonding material to bond the semiconductor element to the first heat dissipation substrate with the first bonding material interposed;
mounting the heat dissipation block on the electrode of the semiconductor element with a second bonding material interposed, and
further mounting a second heat dissipation substrate on the heat dissipation block with a third bonding material interposed; and
heating the second bonding material and the third bonding material to allow the second bonding material and the third bonding material to cover a side surface of the heat dissipation block, and to bond the electrode and the second heat dissipation substrate.
